(19) United States
(12) Patent Application Publication
(10) Pub. No.: US 2017/0053873 A1
(43) Pub. Date: Feb. 23, 2017

(54) Flexible integrated circuit devices and methods for manufacturing the same

(71) Applicant: Huilong Zhu, Poughkeepsie, NY (US)

(72) Inventor: Huilong Zhu, Poughkeepsie, NY (US)

(21) Appl. No.: 14/756,284

(22) Filed: Aug. 19, 2015

(51) Int. Cl. H01L 23/538; H01L 27/02; H01L 21/762; H01L 21/683; H01L 23/498; H01L 21/306

(52) U.S. Cl. CPC H01L 23/5387; H01L 23/5386; H01L 23/49894; H01L 21/30604; H01L 21/762; H01L 21/6835; H01L 27/0207; H01L 2221/6835

(57) ABSTRACT

The present disclosure relates to a flexible integrated circuit device and a method for manufacturing the same. The flexible integrated circuit device includes a plurality of semiconductor islands which have respective semiconductor devices and are separated from each other. A plurality of interconnect members couple adjacent ones of the semiconductor islands to each other. A support layer is attached to the plurality of semiconductor islands. The plurality of interconnect members each have ends extending into the semiconductor islands and middle portions between the semiconductor islands. Thus, the flexible integrated circuit device can be bent, and can also be stretched in at least one direction. The flexible integrated circuit device allows both characteristics of bending deformation and expansion deformation to fulfill requirements of wearable electronics, reduce manufacturing cost, and improved reliability.

### CLAIM OF PRIORITY

This application claims priority to Chinese Application No. 201410459042.1, filed on Sep. 10, 2014 (published as CN 104347591 A), which is hereby incorporated by reference.

### BACKGROUND OF THE DISCLOSURE

Field of the Disclosure

The present invention relates to integrated circuits, and more particularly, to a flexible integrated circuit device and a method for manufacturing the same.

Description of the Related Art

The flexible integrated circuit can be bended or stretched under an external force, while maintaining integrity and functionality of the integrated circuit. Also, the flexible integrated circuit can also be used for providing a large-area electronic devices with low cost. Thus, the flexible integrated circuit can be widely used in electronic products such as wearable electronics and the like.

A semiconductor chip is typically made from a silicon wafer and is rigid itself. Thus, the semiconductor chip is easily to be damaged under the external force because it is difficult to be bended or stretched. However, it has been found that a thin semiconductor layer is flexible when it has a thickness smaller than 50 micrometers. A known method for forming a flexible circuit includes firstly forming semiconductor devices of the integrated circuit in a thin semiconductor layer of a silicon wafer, and then transferring the thin semiconductor layer from the silicon wafer to a flexible sheet. This method has an important disadvantage that the thin semiconductor layer should have a small thickness, which causes many problems when designing and manufacturing the integrated circuit. Moreover, a large amount of semiconductor material is removed due to etching when the thin semiconductor layer is transferred, which increases manufacturing cost of the flexible integrated circuit.

Another known method for manufacturing a flexible integrated circuit includes separating semiconductor devices in a semiconductor substrate into a plurality of rigid substrate islands. Interconnect members, which are elastically deformable, are formed between the substrate islands, so that the rigid substrate islands can be formed together as a flexible network of the semiconductor islands. The network of the substrate islands may be attached to a resin sheet to increase its mechanical strength. The interconnect members may provide only mechanical support, or both mechanical support and electrical connections between different substrate islands. The interconnect members are typically made of metal, and may be formed on an insulating layer. This method has an important disadvantage that the interconnect members suffer from mechanical stress. The interconnect members have thermal expansion coefficient different from that of the insulating layer. Fracture easily occurs in manufacturing process or in actual usage. Consequently, the flexible integrated circuit may have poor yield and reliability.

Moreover, in the above known methods, etching is performed at a back side of the semiconductor substrate for thinning when the thin semiconductor layer is transferred or the substrate islands are separated from each other. Etching at the back side is time consuming and a large amount of semiconductor material is removed, which increases manufacturing cost of the flexible integrated circuit.

### BRIEF DESCRIPTION OF THE DISCLOSURE

In view of this, the present disclosure provides an improved flexible integrated circuit device and an assembly thereof and a method for manufacturing the same, for improving reliability of the flexible integrated circuit and reducing its manufacturing cost.

According to one aspect of the present disclosure, there is provided a flexible integrated circuit device, comprising: a plurality of semiconductor islands which have respective semiconductor devices and are separated from each other; a plurality of interconnect members which couple adjacent ones of the semiconductor islands to each other; and a support layer which is attached to the plurality of semiconductor islands, wherein the plurality of interconnect members each have ends extending into the semiconductor islands and middle portions between the semiconductor islands, so that the flexible integrated circuit device is bendable, and is stretchable in at least one direction.

Preferably, the middle portions of the plurality of interconnect members have exposed top surfaces.

Preferably, the middle portions of the plurality of interconnect members are suspended above gaps between the plurality of semiconductor islands.

Preferably, the middle portions of the plurality of interconnect members have a curved shape or a folding shape.

Preferably, the middle portions of the plurality of interconnect members have a shape selected from a straight line, a folding line, an S-shape curve, a zigzag-shape curve.

Preferably, the middle portions of the plurality of interconnect members are arranged as being stretchable in at least one direction.

Preferably, the middle portions of the plurality of interconnect members are arranged as being stretchable in at least two directions.

Preferably, the middle portions of the plurality of interconnect members are made of metal.

Preferably, at least one of the plurality of interconnect members is used for electrically connecting semiconductor devices in adjacent ones of the semiconductor islands.

Preferably, the plurality of interconnect members are each formed from at least one metal layer.

Preferably, at least one of the plurality of interconnect members is formed from a plurality of metal layers.

Preferably, the at least one of the plurality of interconnect members has a tubular structure, with the plurality of metal layers forming bottom, top and side walls of the tubular structure respectively.

Preferably, the plurality of metal layers further form a core of the tubular structure.

Preferably, the tubular structure has mesh side walls.

Preferably, the support layer is made of one selected from a group consisting of polyethylene terephthalate (PET), polyvinyl chloride (PVC), polyimide (PI), polyamide-imide (PAI), polyether-imide (PEI), polyether ketone (PEEK) and vinyl acetate ethylene copolymer (EVA).

According to the second aspect of the present disclosure, there is provided an assembly having a flexible integrated circuit device, comprising: a support substrate; and the above flexible integrated circuit device, wherein the flexible integrated circuit device is arranged on the support substrate, or in the support substrate, or as a stack with the support substrate.

Preferably, the support substrate is made of one selected from a group consisting of resin, cloth, and paper.

Preferably, the resin is one selected from a group consisting of polyethylene terephthalate (PET), polyvinyl chloride (PVC), polyimide (PI), polyamide-imide (PAI), polyether-imide (PEI), polyether ketone (PEEK) and vinyl acetate ethylene copolymer (EVA).

Preferably, the middle portions of the interconnect members are arranged in an adhesive or in a resin to maintain a relative distance so that the middle portions of the interconnect members are separated from each other.

According to the third aspect of the present disclosure, there is provided a method for manufacturing a flexible integrated circuit device, comprising: forming a first trench in a semiconductor layer to separate the semiconductor layer into a plurality of semiconductor islands; forming a first portion of an interlayer dielectric to fill the first trench; forming semiconductor devices in the plurality of semiconductor islands; forming a second portion of the interlayer dielectric to cover top surfaces of the plurality of semiconductor islands; forming a plurality of insulating layers on the interlayer dielectric; forming at least one interconnect member in at least one of the plurality of insulating layers; and forming a second trench in the plurality of insulating layers and the interlayer dielectric to separate the plurality of semiconductor islands, which are surrounded by remaining portions of the interlayer dielectric, from each other, wherein in the steps of forming the first trench and forming the second trench, an etching process is performed from a surface of semiconductor layer at which the semiconductor devices are formed.

Preferably, the second trench is aligned to the first trench but has a smaller width.

Preferably, before the step of forming the first trench, the method further comprises: forming a sacrificial layer on the semiconductor substrate; and forming the semiconductor layer on the sacrificial layer.

Preferably, the sacrificial layer has an etching rate different from that of the semiconductor layer and from that of the semiconductor substrate.

Preferably, after the step of forming the second trench, the method further comprises: selectively etching the sacrificial layer with respect to the semiconductor layer and the semiconductor substrate through the second trench; and removing the semiconductor substrate.

Preferably, the semiconductor layer is formed from a portion of the semiconductor substrate, and the semiconductor substrate is a single-crystal semiconductor substrate.

Preferably, the single-crystal semiconductor substrate has different etching rates in different crystal planes.

Preferably, after the step of forming the second trench, the method further comprises: selectively etching a portion of the semiconductor substrate with respect to the interlayer dielectric through the second trench to form an opening having exposed bottom and side walls in the semiconductor substrate; etching the sidewalls laterally through the opening in the semiconductor substrate, with an etchant having different etching rates in different crystal planes, to remove a portion of the semiconductor substrate below the semiconductor layer; and removing the semiconductor substrate.

In the flexible integrated circuit device according to the embodiment of the present disclosure, the middle portions of the interconnect members can be deformed freely. In a preferable embodiment, the middle portions of the interconnect members are suspended. Mechanical characteristic of the flexible integrated circuit device is determined by the support layer, but not restricted by the insulating layer in the flexible integrated circuit device. Thus, the flexible integrated circuit device has improved reliability. The flexible integrated circuit according to the present disclosure can have larger degree of bending due to elastic deformation of the support layer, and can be stretched in at least one direction due to flexibility of the interconnect members. Thus, the flexible integrated circuit according to the present disclosure and the assembly thereof can be used in wearable electronics.

In the method for manufacturing the flexible integrated circuit according to the present disclosure, the semiconductor substrate is etched from a front surface at which semiconductor devices are formed when semiconductor islands are separated from each other. Only a portion of the sacrificial layer above the semiconductor substrate, or only a portion of the semiconductor substrate, is consumed in the process. After the flexible integrated circuit is formed, the remaining portion of semiconductor substrate can still be used for manufacturing semiconductor devices. Thus, the process time can be shorten, and semiconductor material can be used more efficiently.

### BRIEF DESCRIPTION OF THE DRAWINGS

The above and other objects, advantages and features of the present invention will become more fully understood from the detailed description given hereinbelow in connection with the appended drawings, and wherein:

FIGS. 1 to 6, 7b-10b, and 11-13 are cross-sectional views of semiconductor structures at various stages, and FIGS. 7a-10a are top views of the semiconductor structures at some stages, of a method for manufacturing a flexible integrated circuit according to an embodiment of the present disclosure;

FIG. 14 is a perspective view illustrating a flexible integrated circuit according to an embodiment of the present disclosure;

FIGS. 15a and 15b are perspective views illustrating a multilayer interconnect member according to a first embodiment of the present invention; and

FIG. 16 is a perspective view illustrating a multilayer interconnect member according to a second embodiment of the present invention.

### DETAILED DESCRIPTION OF EMBODIMENTS OF THE DISCLOSURE

Exemplary embodiments of the present disclosure will be described in more details below with reference to the accompanying drawings. In the drawings, like reference numerals denote like members. The figures are not drawn to scale, for the sake of clarity. Moreover, some well-known parts may not be shown. For simplicity, the structure of the semiconductor device having been subject to several relevant process steps may be shown in one figure.

It should be understood that when one layer or region is referred to as being “above” or “on” another layer or region in the description of device structure, it can be directly above or on the other layer or region, or other layers or regions may be intervened there between. Moreover, if the device in the figures is turned over, the layer or region will be “under” or “below” the other layer or region.

In contrast, when one layer is referred to as being “directly on” or “on and adjacent to” or “adjoin” another layer or region, there are not intervening layers or regions present. In the present application, when one region is referred to as being “directly in”, it can be directly in another region and adjoins the another region, but not in a implantation region of the another region.

In the present application, the term “semiconductor structure” means generally the whole semiconductor structure formed at each step of the method for manufacturing the semiconductor device, including all of the layers and regions having been formed. The term “source/drain region” means at least one of a source region and a drain region of a MOSFET.

Some particular details of the present disclosure will be described below, such as exemplary semiconductor structures, materials, dimensions, process steps and technologies of the semiconductor device, for better understanding of the present disclosure. However, it can be understood by one skilled person in the art that these details are not always essential for but can be varied in a specific implementation of the disclosure.

Unless the context clearly indicates otherwise, each part of the semiconductor device can be made of material(s) well known to one skilled person in the art. The semiconductor material includes for example group-III-V semiconductor, such as GaAs, InGaAs, InP, and GaN, and group IV semiconductor, such as Si, Ge, and SiC. A gate conductor may be made of any conductive material, such as metal, doped polysilicon, and a stack of metal and doped polysilicon, among others. For example, the gate conductor may be made of one selected from a group consisting of TaC, TiN, TaSiN, HfSiN, TiSiN, TiCN, TaAlC, TiAlN, TiCAl, TaN, PtSix, Ni3Si, Pt, Ru, W, and their combinations. A gate dielectric may be made of SiO2 or any material having dielectric constant larger than that of SiO2. For example, the gate dielectric may be made of one selected from a group consisting of oxides, nitrides, oxynitrides, Hf, silicates, aluminates, and titanates. Moreover, the gate dielectric can be made of those developed in the future, besides the above known materials.

The disclosure can be embodied in various forms, some of which will be described below.

Referring to FIGS. 1 to 13, various stages of a method for manufacturing a flexible integrated circuit device according to an embodiment of the present disclosure will be described hereinbelow.

As shows in FIG. 1, the method starts with a semiconductor substrate 101, such as a silicon wafer. A first semiconductor layer 102 and a second semiconductor layer 103 are formed successively by epitaxy growth on a surface of the semiconductor substrate 101 by a conventional deposition process. For example, the deposition process may be one selected from a group consisting of electron beam evaporation (EBM), chemical vapor deposition (CVD), atomic layer deposition (ALD), and sputtering. The first semiconductor layer 102 and the second semiconductor layer 103 may have different etching rates so that the first semiconductor layer 102 may be used as an etching stop and as a sacrificial layer. In one example, the first semiconductor layer 102 may be an epitaxy silicon-germanium layer with a thickness in a range between about 10 nanometers and 10 micrometers, the second semiconductor layer 103 may be an epitaxy silicon layer with a thickness in a range between about 10 nanometers and 1 micrometer.

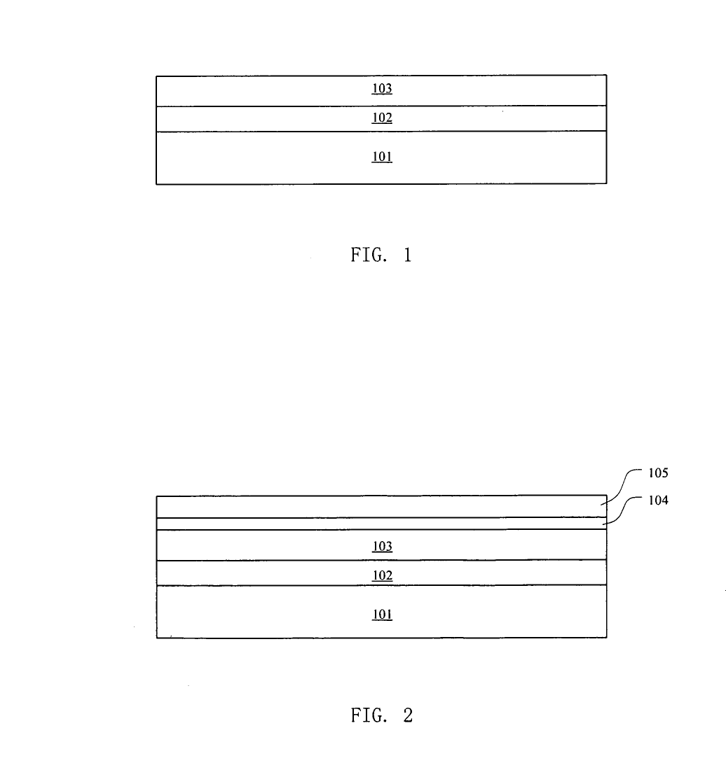

Next, a buffer layer 104 and a protection layer 105 are formed successively on a surface of the second semiconductor layer 103, as shown in FIG. 2. In one example, the buffer layer 104 may be an oxide layer with a thickness in a range between about 5 nanometers and about 20 nanometers, the protection layer 105 may be a nitride layer with a thickness in a range between about 50 nanometers and about 200 nanometers. The buffer layer 104 is disposed between the protection layer 105 and the second semiconductor layer 103, for releasing stress due to the protection layer 105 if being formed directly on the second semiconductor layer 105.

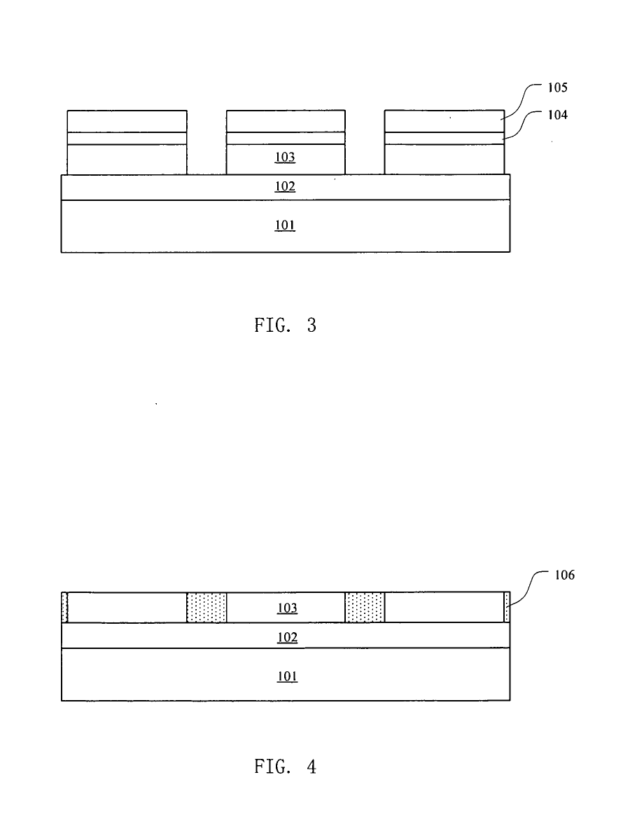

Next, a photoresist layer is formed on a surface of the protection layer 105, and then patterned by lithography to be a mask with openings therein. Etching is performed through the mask. Exposed portions of the protection layer 105, the buffer layer 104 and the second semiconductor layer 103 are removed from top to bottom through the opening in the mask, by dry etching such as ion beam milling, plasma etching, reactive ion etching, laser ablation and the like, or by wet etching using a selective solution of etchant. Due to selectivity of the etchant, the etching stops at the surface of the first semiconductor substrate 102. Then, the photoresist layer is removed by ashing or dissolution with a solvent. Trenches are formed by etching, which separate the second semiconductor layer 103 into a plurality of semiconductor islands, as shown in FIG. 3.

Next, an interlayer dielectric 106 is then formed on the surface of the semiconductor structure by the above conventional deposition process. In an example, the interlayer dielectric 106 is an oxide layer with a thickness large enough to fill up the trenches surrounding the semiconductor islands. The surface of the semiconductor structure is planarized by chemical mechanical polishing (CMP). The CMP stops at the top surface of the protection layer 105 and removes a portion of the interlayer dielectric 106 outside the trenches. The remaining portion of the interlayer dielectric 106 in the trenches is then selectively etched back with respect to the protection layer 105. The protection layer 105 and the buffer layer 104 are then removed by selective etching with respect to the second semiconductor layer 103, so as to expose the surface of the second semiconductor layer 103. The second semiconductor layer 103 is separated into a plurality of semiconductor islands surrounded by the interlayer dielectric 106, as shown in FIG. 4.

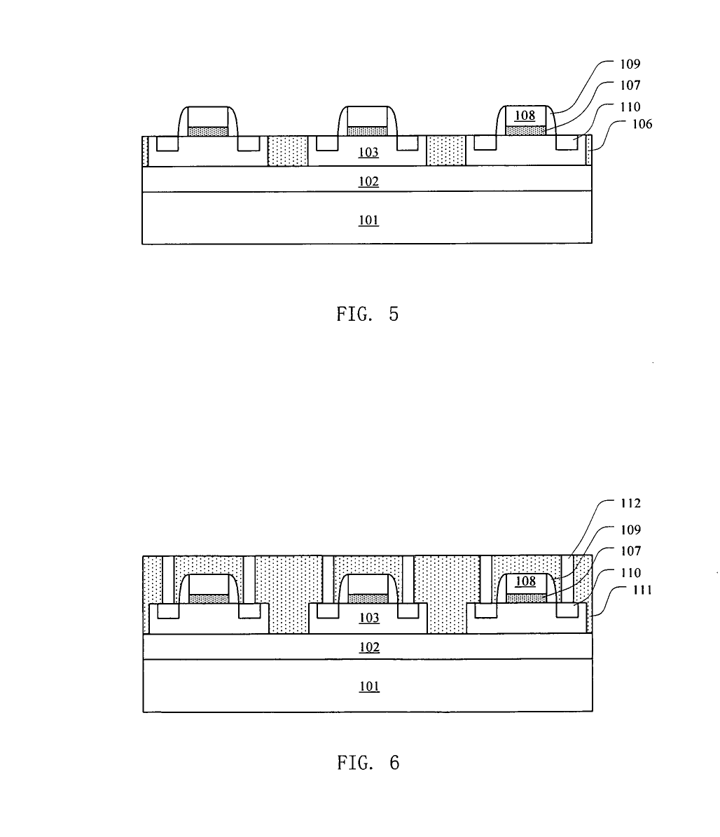

Next, MOSFETs are formed in various islands of the second semiconductor layer 103, as shown in FIG. 5. Only as an example, three semiconductor islands, each of which includes one MOSFET, are shown in FIG. 5. It should be understood that the semiconductor structure may have any number of semiconductor islands and any number of MOSFETs. The semiconductor structure may also include other semiconductor devices such as capacitors, resistors, and the like, all of which are integrated into at least one semiconductor island.

A conventional process for forming a MOSFET in a semiconductor layer may include the following several steps. A gate dielectric 107 and a gate conductor 108 are formed successively on the surface of the semiconductor structure by the above conventional deposition process. A gate stack is then defined by etching and lithography with a photoresist layer as a mask. A conformal nitride layer is then formed on the surface of the semiconductor structure by the above conventional deposition processes. Lateral portions of the nitride layer are removed by anisotropic etching, for example, reactive ion etching. Consequently, only vertical portions of the nitride layer remain at side walls of the gate stack to form gate spacers 109. Ion implantation is then performed, with the gate conductor 108 and the gate spacer 109 together as a hard mask, and with a photoresist layer as an additional mask, to form source/drain regions 110 in the second semiconductor layer 103.

An N-type semiconductor layer or region may be formed by implanting an N-type dopant such as P or As in the semiconductor layer or region. A P-type semiconductor layer or region may be formed by implanting a P-type dopant such as B in the semiconductor layer or region. By controlling implantation parameters, such as implantation energy and dosage, the dopant may reach a predetermined depth and may have a predetermined doping concentration.

Next, an interlayer dielectric 111 is then formed on the surface of the semiconductor structure by the above conventional deposition process, so as to cover various parts of the MOSFETs. In an example, the interlayer dielectric 111 is an oxide layer, and may be merged with the interlayer dielectric 106 having been formed. If necessary, the surface of the semiconductor structure may be planarized by CMP after forming the interlayer dielectric 111.

A photoresist mask is then formed by lithography to have openings therein for defining conductive vias. Etching is performed through the photoresist mask to form openings in the interlayer dielectric 111 to reach the source/drain regions of the MOSFETs. After removing the photoresist mask, conductive material is deposited on the semiconductor structure by the above conventional deposition process. In an example, the conductive material is copper. The conductive material should have a thickness large enough to fill up the openings in the interlayer dielectric 111. A portion of the conductive material outside the openings is removed by CMP. Remaining portions of the conductive material in the openings become conductive vias 111, as shown in FIG. 6.

The conductive vias 112 have bottoms reaching the source/drain regions of the MOSFETs. Other conductive vias may also be formed to electrically connecting other semiconductor devices. The conductive vias 112 have tops which are exposed at the surface of the interlayer dielectric 111.

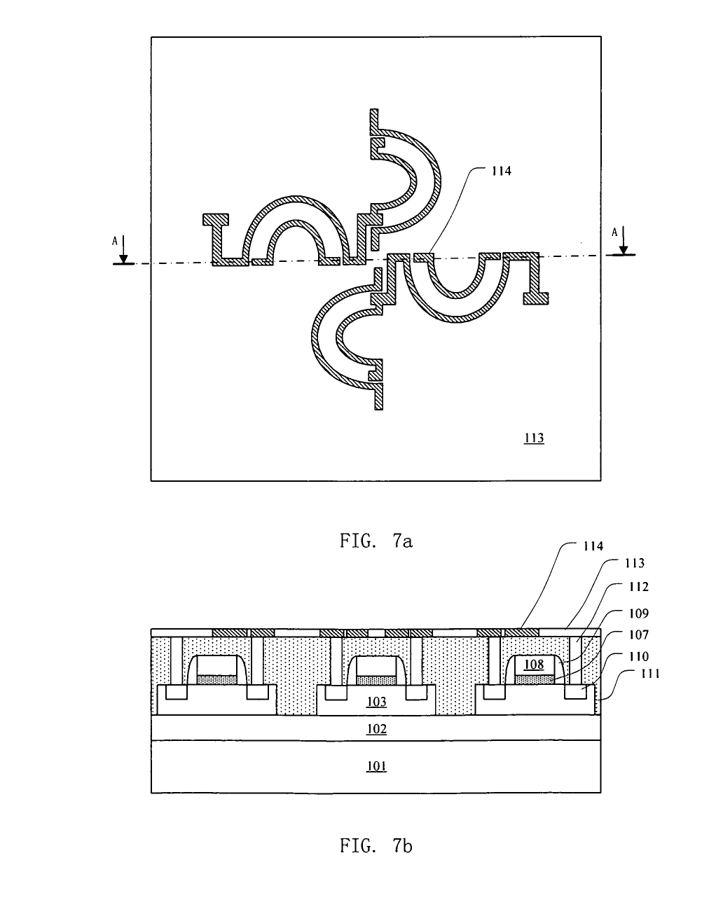

Next, a first insulating layer 113 is then formed on the surface of the semiconductor structure by the above conventional deposition process. In an example, the first insulating layer 113 is made of nitrides. Trenches are then formed by etching and lithography in the first insulating layer 113, with a photoresist layer as a mask, for defining interconnect members. The trenches penetrate the first insulating layer 113, with the exposed surface of the interlayer dielectric 111 as bottoms of the trenches. Conductive material is deposited on the semiconductor structure by the above conventional deposition process. In an example, the conductive material is copper. The conductive material should have a thickness large enough to fill up the trenches in the first insulating layer 113. A portion of the conductive material outside the trenches is removed by CMP. Remaining portions of the conductive material in the trenches become interconnect members 114, as shown in FIGS. 7a and 7b.

FIGS. 7a and 7b are a top view and a cross-sectional view illustrating a semiconductor structure at this stage, respectively. A line AA is shown in FIG. 7a, along which the cross-sectional view is taken and shown in FIG. 7b. Actually, all of the cross-sectional views in FIGS. 1 to 13 are taken along the line AA.

Each of the interconnect members 114 includes two ends extending into the semiconductor islands and a middle portion between the semiconductor islands. The ends of the interconnect members 114 further extend inside the semiconductor islands. Optionally, the ends of the interconnect members 114 contact the conductive vias 112 for electrical connection. The middle portions of the interconnect members 114 have a curved shape or a folding shape, such as a smooth curve, a folding line, an S-shape curve, a zigzag-shape curve. Moreover, the middle portions of two adjacent interconnect members 114 may be connected with each other by additional interconnect members, to maintain a distance between the two adjacent interconnect members 114 in subsequent steps.

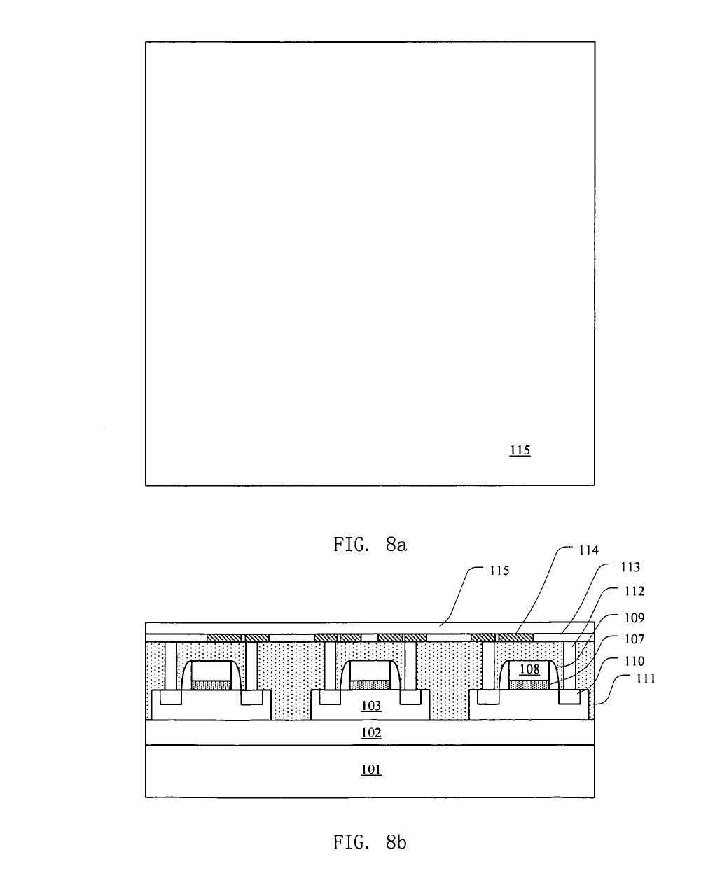

Next, a second insulating layer 115 is then formed on the surface of the semiconductor structure by the above conventional deposition process, as shown in FIG. 8. In an example, the second insulating layer 115 is made of oxides. The second insulating layer 115 covers the first insulating layer 113 and the interconnect members 114 therein.

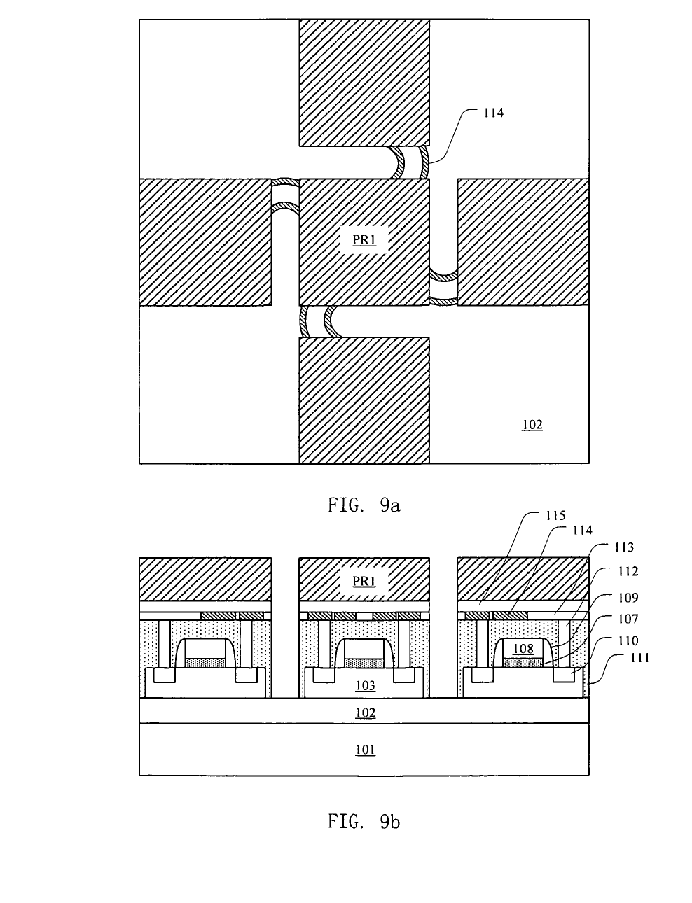

Next, a photoresist layer is formed on a surface of the semiconductor structure, and then patterned by lithography to be a mask PR1 with openings therein. Exposed portions of the second insulating layer 115, the first insulating layer 113 and the interlayer dielectric 111 are removed successively by etching from top to bottom through the photoresist mask PR1. Due to selectivity of the etchant, the etching stops at the surface of the first semiconductor substrate 102. Then, the photoresist layer is removed by ashing or dissolution with a solvent. Trenches are formed by etching, which separate the second semiconductor layer 103 into a plurality of semiconductor islands surrounded by the interlayer dielectric 111, as shown in FIG. 9.

The trench pattern shown in FIG. 9 is similar to the trench pattern shown in FIG. 3, but has a smaller width. Thus, a portion of the interlayer dielectric 111 remains and surrounds the semiconductor islands.

The second insulating layer 115 are removed by etching in FIG. 9 to expose top surfaces of the middle portions of the interconnect members 114. Preferably, isotropic etching is performed after forming the trenches by etching, to completely remove portions of the interlayer dielectric 111 below the middle portions of the interconnect members 114. Consequently, the middle portions of the interconnect members are suspended. A time period of etching is well controlled so that the portions of the interlayer dielectric 111 below the middle portions of the interconnect members 114 are completely removed, while remaining portions of the interlayer dielectric 111 still surrounds to semiconductor islands. Then, the photoresist layer mask PR1 is removed by ashing or dissolution with a solvent.

Due to such a preferable step, both the portions of an insulating layer above and below the interconnect members 114 are removed by etching, and mechanical stress due to thermal expansion coefficient difference between the interconnect members 114 and the insulating layer can be avoided.

Next, a support layer 121 is adhered to the second insulating layer 115, as shown in FIG. 10. The support layer 121 is made of one selected from a group consisting of polyethylene terephthalate (PET), polyvinyl chloride (PVC), polyimide (PI), polyamide-imide (PAI), polyether-imide (PEI), polyether ketone (PEEK) and vinyl acetate ethylene copolymer (EVA). Preferably, the support layer 121 is made of vinyl acetate ethylene copolymer (EVA). The support layer 121 may be a sheet including openings, or a net.

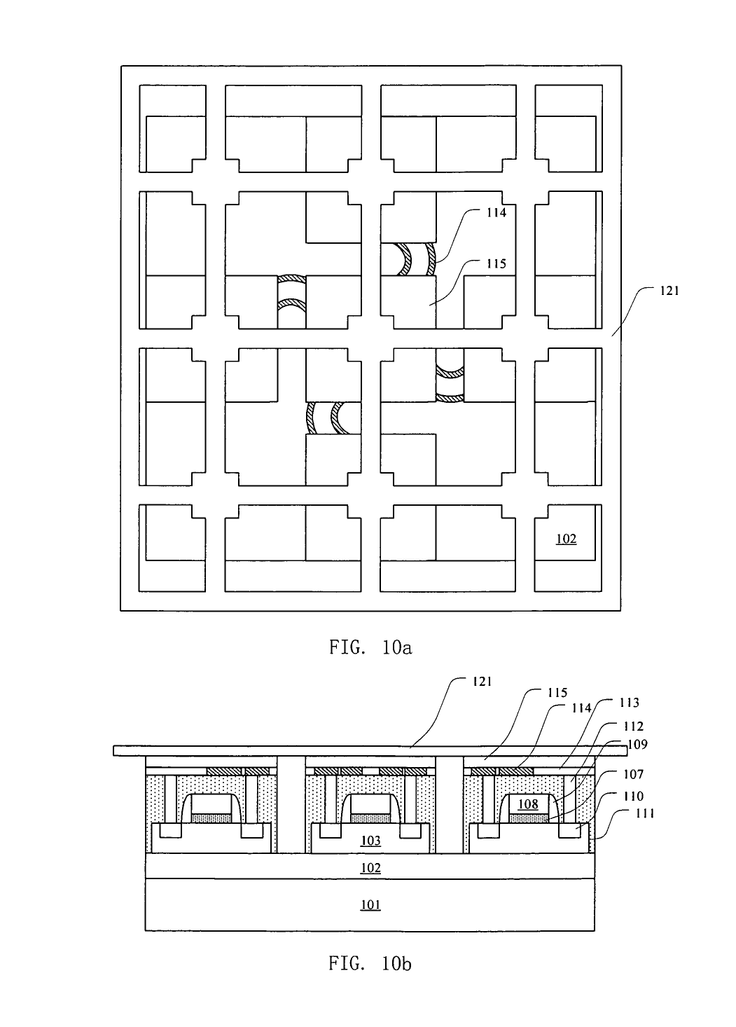

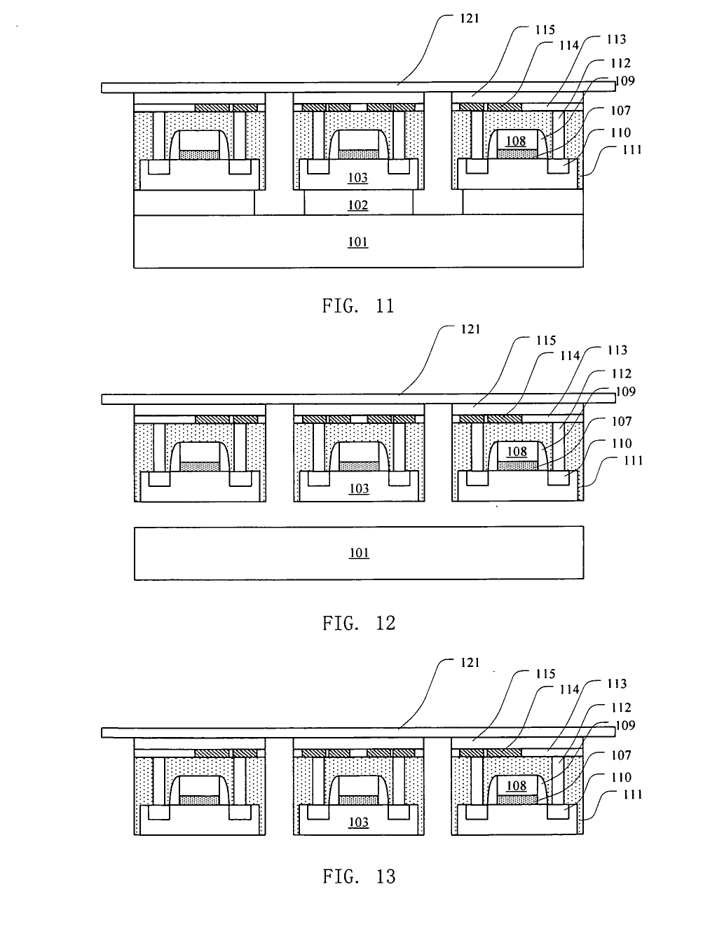

Next, the first semiconductor layer 102 is selectively removed by isotropic etching, with respect to the second insulating layer 115, the first insulating layer 113, the interlayer dielectric 111, the second semiconductor layer 103 and the semiconductor substrate 101, and without using a photoresist mask, In the etching, an etchant reaches an exposed surface of the first semiconductor layer 102 through the openings in the support layer 121 and through the trenches between the semiconductor islands, as shown in FIG. 11. The etching continues by etching laterally to remove remaining portions of the first semiconductor layer 102, as shown in FIG. 12. After etching, some layers are supported by the support layer 121 and separated from the semiconductor substrate 101 to form a flexible integrated circuit device, as shown in FIG. 13.

Different from a conventional process including etching from a back side, the first semiconductor layer 102 is used as a sacrificial layer in the present process, and etching is performed from a front side when separating the semiconductor islands from the semiconductor substrate. The front side of the semiconductor structure refers to the surface where the semiconductor devices are formed. Consequently, only semiconductor material of the first semiconductor layer 102 is consumed. The remaining portion of the semiconductor substrate can still be used for manufacturing other semiconductor devices. Thus, the process time can be shorten, and the semiconductor material can be used more efficiently.

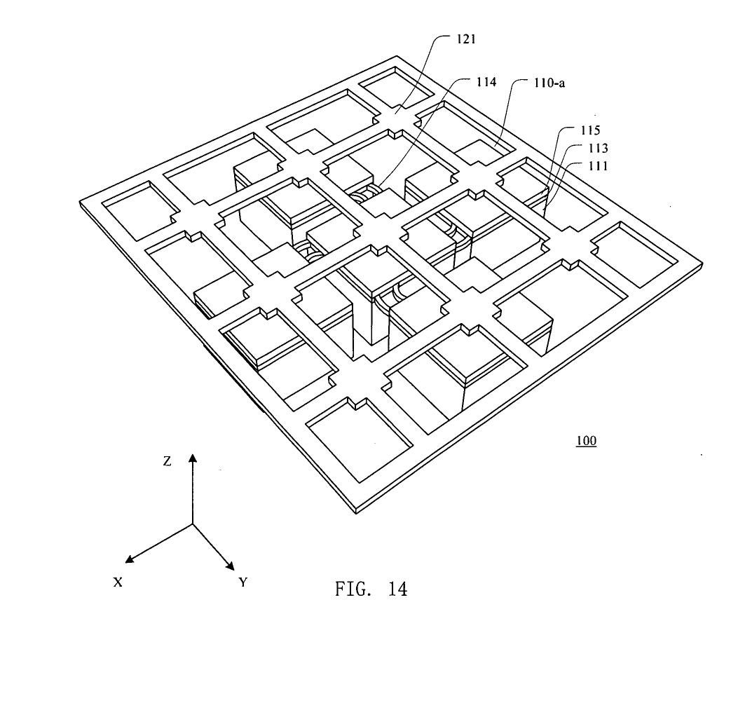

FIG. 14 is a perspective view illustrating a flexible integrated circuit device 100 according to an embodiment of the present disclosure. The flexible integrated circuit device 100 includes a plurality of semiconductor islands which are separated from each other. Five semiconductor islands are shown in FIG. 14, as an example. Each semiconductor island includes a semiconductor layer 103, an interlayer dielectric 111 on the semiconductor layer 103 and surrounding side walls of the semiconductor layer 103, a first insulating layer 113 on the interlayer dielectric 111, a second insulating layer 115 on the first insulating layer 113, and a support layer 121 attached to a surface of the second insulating layer 115. Two adjacent ones of the semiconductor islands are still connected by interconnect members 114.

As mentioned above, active regions of semiconductor devices are formed in the semiconductor layer 103. If necessary, gate stacks of the semiconductor devices may be formed above the semiconductor layer 103. Conductive vias extend through the interlayer dielectric 111 and provide electrical connect with the semiconductor devices.

Each of the interconnect members 114 includes two ends extending into the semiconductor islands and a middle portion between the semiconductor islands. The ends of the interconnect members 114 further extend inside the semiconductor islands. The ends of the interconnect members 114 are located in the first insulating layer 113 and covered by the second insulating layer 115, and thus is secured to the semiconductor islands. The middle portions of the interconnect members 114 have a curved shape or a folding shape, such as a smooth curve, a folding line, an S-shape curve, a zigzag-shape curve. Compared to a conventional flexible integrated circuit device, the present flexible integrated circuit device 100 includes the interconnect members 114 with a middle portion being suspended. Mechanical characteristic of the flexible integrated circuit device 100 is determined by the support layer 121, but not restricted by the insulating layer in the flexible integrated circuit device.

The conventional flexible integrated circuit device can be bended due to elastic deformation of the interconnect members. As a comparison, the present flexible integrated circuit device 100 can have a larger degree of bending due to elastic deformation of the support layer 121. Moreover, the middle portions of the interconnect members 114 are suspended, and the interconnect members 114 are disposed at side walls of the semiconductor islands in at least two directions. Thus, the present flexible integrated circuit device 100 can be stretched in at least two directions. The stretching direction is alone X axis and Y axis in FIG. 14.

Furthermore, the above flexible integrated circuit device 100 can be transferred to a support substrate of resin, cloth, paper, or the like, and then is encapsulated as an assembly. The resin substrate is made of one selected from a group consisting of polyethylene terephthalate (PET), polyvinyl chloride (PVC), polyimide (PI), polyamide-imide (PAI), polyether-imide (PEI), polyether ketone (PEEK) and vinyl acetate ethylene copolymer (EVA).

The flexible integrated circuit device is arranged on the support substrate, or in the support substrate, or as a stack with the support substrate. Before encapsulation, the flexible integrated circuit 100 may be stretched to some extend if necessary. In the assembly, the middle portions of the interconnect members 114 of the flexible integrated circuit device 100 are arranged in an adhesive or in a resin to maintain a relative distance so that the middle portions of the interconnect members are separated from each other. Thus, the present encapsulated assembly can be used in wearable electronics because it is bendable and stretchable.

In the above embodiment, the first semiconductor layer 102 and the second semiconductor layer 103 are formed on the semiconductor substrate 101. The first semiconductor layer 102 is used as a sacrificial layer when separating the semiconductor substrate 101. Alternatively, a semiconductor substrate 101 with a (111) lattice plane as a surface can be used, without the need for the first semiconductor layer 102 and the second semiconductor layer 103. After forming the semiconductor devices and the interconnect members, the following steps continue and replace those shown in FIGS. 11 to 13.

Portions of the semiconductor substrate 101 are selectively removed with respect to the second insulating layer 115, the first insulating layer 113, and the interlayer dielectric 111, without using a photoresist mask. In the etching, a first etchant reaches an exposed surface of the semiconductor substrate 101 through the openings in the support layer 121 and through the trenches between the semiconductor [symbol] islands, to form openings in the semiconductor substrate 101. A second etchant is then used, which exhibits selective etching with respect to the lattice plane, and thus starts anisotropic etching through the openings in the semiconductor substrate 101. For example, the second etchant may be a solution of tetramethylammonium hydroxide (TMAH) or potassium hydroxide (KOH). Due to selectivity, the etching extends laterally at the side walls of the openings in the semiconductor substrate 101, and thus removes exposed side walls of the openings in the semiconductor substrate 101 to form undercuts below the semiconductor islands. The etching continues laterally to remove remaining portions of the side walls of the openings in the semiconductor substrate 101. After etching, some layers are supported by the support layer 121 and separated from the semiconductor substrate 101 to form a flexible integrated circuit device.

Moreover, the interconnect members are described as being a single metal layer embedded in the first insulating layer and covered by the second insulating layer in the above embodiments. Alternatively, the interconnect members may have a more complex structure. For example, the interconnect members may have a tubular structure in a plurality of insulating layers, with a plurality of metal layers forming bottom, top and side walls of the tubular structure respectively. If necessary, a conductive core may also be formed from a metal layer in the tubular structure.

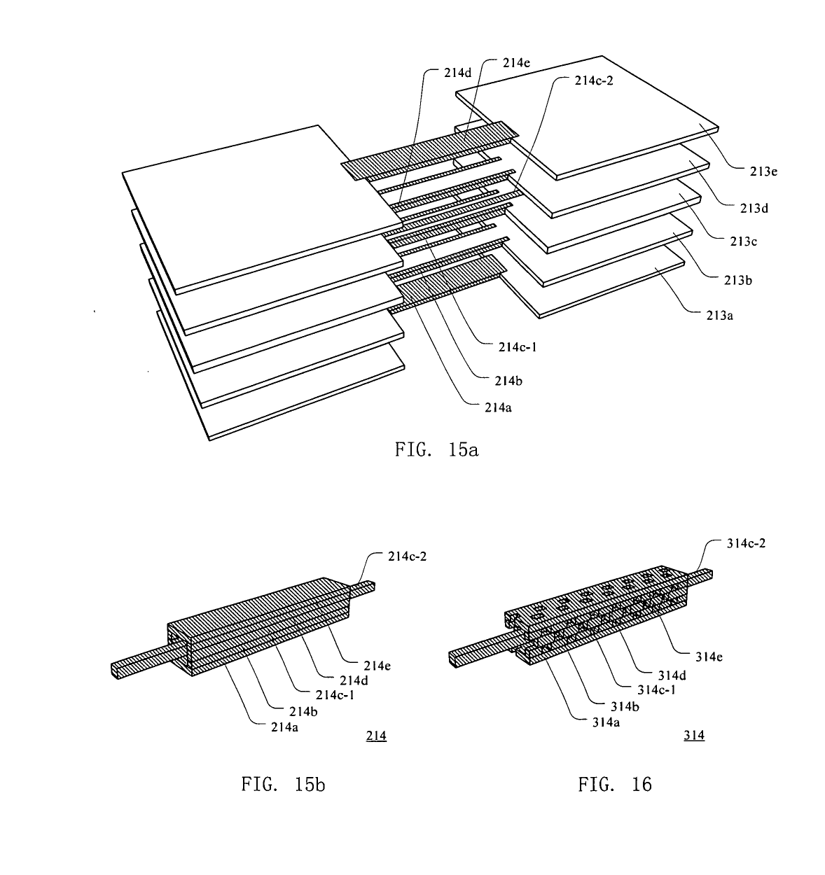

FIGS. 15a and 15b are perspective views of a multilayer interconnect member according to a first embodiment of the present invention. Different insulating layers and metal layers of the interconnect member are shown as being separated from each other in FIG. 15a, and only the metal layers are shown in FIG. 15b, only for the sake of clarity.

In this embodiment, the multilayer interconnect member includes five insulating layers 213a-213e, one stacked above the other, and five metal layers 214a-214e are embedded in the five insulating layers respectively. Each of the five metal layers 214a-214e extend from one end to the other end of the interconnect member. The five metal layers 214a-214e constitute the tubular structure 214 together. Specifically, the metal layers 214a and 214e form the bottom and the top of the tubular structure 214 respectively, and the metal layer 214b and a first portion 214c-1 of the metal layer 214c and the metal layers 214d form side walls of the tubular structure 214 together, which provides an outer wall of the tubular structure 214. A second portion 214c-2 of the metal layer 214c forms a conductive core of the tubular structure 214c, and may be used as a signal wire in the interconnect member.

The tubular structure 214 is formed mainly at the middle portion of the interconnect member, i.e. a portion of the interconnect member between two semiconductor islands. The tubular structure 214 may further extends inside the semiconductor islands. The conductive core of the tubular structure 214 may be exposed to semiconductor devices in the semiconductor islands to provide electrical connection.

In an actual electronic product, the outer wall of the tubular structure 214 may be grounded and the conductive core of the tubular structure 214 may be used as a conductive wire. The tubular structure 214 is preferable, because it provides a shielded signal wire between the semiconductor islands, not only for improved electrical properties, but also for avoiding short circuit which otherwise occurs in a case two adjacent interconnect members contact each other when the flexible integrated circuit device is stretched.

The interconnect member between the semiconductor islands further includes insulating material inside the tubular structure 214. Actually, the insulating material is a portion of the respective insulating layer. The insulating material in the tubular structure 214 is used for insulating the conductive core from the outer wall, while the tubular structure 214 can still maintain good elastic deformation and plastic deformation.

Although the tubular structure 214 includes only one conductive core 214c-2 in FIGS. 15a and 15b, it should be understood that the tubular structure 214 can have a plurality of conductive cores arranged in one or more levels. In other words, a plurality of signal wires may be formed in one conductive member. Moreover, the tubular structure 214 may not be a straight line. At least the middle portion of the tubular structure 214 between the semiconductor islands has a curved shape or a folding shape, such as a smooth curve, a folding line, an S-shape curve, a zigzag-shape curve. Even in a case that the interconnect member has a tubular structure 214 with insulating material therein, the interconnect member is still stretchable due to its shape.

FIG. 16 is a perspective view of a multilayer interconnect member according to a second embodiment of the present invention, in which only metal layers of the interconnect member are shown, for the sake of clarity.

In this embodiment, the multilayer interconnect member includes five insulating layers 313a-313e, one stacked above the other, and five metal layers 314a-314e are embedded in the five insulating layers respectively. Different from the first embodiment, at least one metal layer is not a continuous layer, or includes a plurality of through holes. The five metal layers 314a-314e constitute the tubular structure 314 together. Specifically, the metal layers 314a and 314e form the bottom and the top of the tubular structure 314 respectively, and the metal layer 314b and a first portion 314c-1 of the metal layer 314c and the metal layers 314d form side walls of the tubular structure 314 together, which provides an outer wall of the tubular structure 314. Because at least one metal layer is not a continuous layer or include through holes, the tubular structure has an outer wall like a net. A second portion 314c-2 of the metal layer 314c forms a conductive core of the tubular structure, and may be used as a signal wire in the interconnect member.

Although the metal layer 314b, the first portion 314c-1 of the metal layer 314c, and the metal layer 314e may not be a continuous layer itself, adjacent ones of these metal layers contact each other. Thus, the outer wall of the tubular structure still provides a continuous conductive path from one end to the other end of the interconnect member. The tubular structure with an outer wall formed as a net can further reduce mechanical stress due to thermal expansion coefficient difference between the metal layers and the insulating layers.

Other aspects of the multilayer interconnect member according to the second embodiment of the disclosure are the same as those of the multilayer interconnect member according to the first embodiment of the disclosure.

It should also be understood that the relational terms such as “first”, “second”, and the like are used in the context merely for distinguishing one element or operation form the other element or operation, instead of meaning or implying any real relationship or order of these elements or operations. Moreover, the terms “comprise”, “comprising” and the like are used to refer to comprise in nonexclusive sense, so that any process, approach, article or apparatus relevant to an element, if follows the terms, means that not only said element listed here, but also those elements not listed explicitly, or those elements inherently included by the process, approach, article or apparatus relevant to said element. If there is no explicit limitation, the wording “comprise a/an . . . ” does not exclude the fact that other elements can also be included together with the process, approach, article or apparatus relevant to the element.

Although various embodiments of the present invention are described above, these embodiments neither present all details, nor imply that the present invention is limited to these embodiments. Obviously, many modifications and changes may be made in light of the teaching of the above embodiments. These embodiments are presented and some details are described herein only for explaining the principle of the invention and its actual use, so that one skilled person can practice the present invention and introduce some modifications in light of the invention. The invention is intended to cover alternatives, modifications and equivalents that may be included within the spirit and scope of the invention as defined by the appended claims.

1. A flexible integrated circuit device, comprising:
a plurality of semiconductor islands which have respective semiconductor devices and are separated from each other;
a plurality of interconnect members which couple adjacent ones of said semiconductor islands to each other; and
a support layer which is attached to said plurality of semiconductor islands, wherein said plurality of interconnect members each have ends extending into said semiconductor islands and middle portions between said semiconductor islands, so that said flexible integrated circuit device is bendable, and is stretchable in at least one direction; and
wherein said plurality of interconnect members comprise a plurality of metal layers, at least one of said plurality of interconnect members has a tubular structure, with said plurality of metal layers forming bottom, top and side walls of said tubular structure respectively.

2. The flexible integrated circuit device according to claim 1, wherein said middle portions of said plurality of interconnect members have exposed top surfaces.

3. The flexible integrated circuit device according to claim 2, wherein said middle portions of said plurality of interconnect members are suspended above gaps between said plurality of semiconductor islands.

4. The flexible integrated circuit device according to claim 1, wherein said middle portions of said plurality of interconnect members have a curved shape or a folding shape.

5. The flexible integrated circuit device according to claim 4, wherein said middle portions of said plurality of interconnect members have a shape selected from a straight line, a folding line, an S-shape curve, a zigzag-shape curve.

6. The flexible integrated circuit device according to claim 1, wherein said middle portions of said plurality of interconnect members are arranged as being stretchable in at least one direction.

8. The flexible integrated circuit device according to claim 1, wherein at least one of said plurality of interconnect members is used for electrically connecting semiconductor devices in adjacent ones of said semiconductor islands.

9-10. (canceled)

11. The flexible integrated circuit device according to claim 1, wherein said plurality of metal layers further form a core of said tubular structure.

12. The flexible integrated circuit device according to claim 1, wherein said tubular structure has an outer wall of a net.

13. The flexible integrated circuit device according to claim 1, wherein said support layer is made of one selected from a group consisting of polyethylene terephthalate (PET), polyvinyl chloride (PVC), polyimide (PI), polyamide-imide (PAD, polyether-imide (PEI), polyether ketone (PEEK) and vinyl acetate ethylene copolymer (EVA).

14. An assembly having a flexible integrated circuit device, comprising:
a support substrate; and
a flexible integrated circuit device according to claim 1,
wherein said flexible integrated circuit device is arranged on said support substrate, or in said support substrate, or as a stack with said support substrate.

15. The assembly according to claim 14, wherein said support substrate is made of one selected from a group consisting of resin, cloth, and paper.

16. The assembly according to claim 14, wherein said middle portions of said interconnect members are arranged in an adhesive or in a resin to maintain a relative distance so that said middle portions of said interconnect members are separated from each other.

17-20. (canceled)
